(19) United States
(12) Patent Application Publication
(10) Pub. No.: US 2018/0355477 A1
(43) Pub. Date: Dec. 13, 2018

(54) THERMAL COATING SYSTEM WITH ALUMINIDE

(71) Applicant: PRATT & WHITNEY CANADA CORP., Longueuil (CA)

(72) Inventors: Aleksandar KOJOVIC, Oakville (CA); Sri SREEKANTH, Mississauga (CA); Robert SZE, Mississauga (CA)

(21) Appl. No.: 15/616,415

(22) Filed: Jun. 7, 2017

(51) Int. Cl. C23C 16/06; C23C 4/134; F23R 3/00

(52) U.S. Cl. CPC C23C 16/06; F23R 3/002; C23C 4/134

(57) ABSTRACT

A coated component of a gas turbine engine having a hot side and a cold side. The component includes a metallic substrate forming a base structure of the component. The metallic substrate has a first surface on the hot side and a second surface on the cold side. A thermal coating system on the metallic substrate includes a first aluminide layer in direct contact with the second surface on the cold side of the component and a first bond layer overlying the first aluminide layer on the cold side of the component.

### TECHNICAL FIELD

The application relates generally to coating systems for gas turbine engine components, and more particularly to thermal coating systems including an aluminide layer.

### BACKGROUND

The hot surfaces (i.e. those exposed to prolonged elevated temperatures) of metal components in gas turbine engines are frequently coated with a Thermal Coating System (TCS)—sometimes called Thermal Barrier Coating (TBC). The remaining surfaces (i.e. cold surfaces) of such components are also frequently coated with a layer of oxidation resistant coating, such as an aluminide coating.

Known TCS thus generally include a ceramic layer on the hot surface and an aluminide layer only on the cold surface of the metal substrate. It is generally assumed that contamination (by other coating materials, such as aluminide coating for example) of the TCS reduces its spallation life. To avoid contamination of the TCS coating on the hot surface during application of the aluminide coating on the cold surface, the hot surface of the component is typically masked to prevent any of the aluminide coating to contaminate the hot side surface. However, masking processes are time and cost intensive, and thus greatly increase the production cost of the gas turbine coated component.

### SUMMARY

There is accordingly provided a method of applying a thermal coating to a gas turbine engine component, the method comprising the steps of: applying a first aluminide layer to a hot surface of the component, the hot surface in use adapted to be exposed to a hot environment of the gas turbine engine; applying a second aluminide layer to a cold surface of the component, the cold surface opposed to the hot surface; applying a first bond layer over the first aluminide layer on the hot surface of the component; applying a second bond layer over the aluminide layer on the cold surface of the component; and applying a ceramic layer on the first bond layer on the hot surface of the component.

There is also provided a coated component of a gas turbine engine having a hot side adapted to be exposed to hot combustion gases and a cold side opposite the hot side, the coated component comprising: a metallic substrate forming a base structure of the coated component, the metallic substrate having a first surface on the hot side of the coated component and a second surface on the cold side of the coated component; and a thermal coating system on the metallic substrate, the thermal coating system including: a first aluminide layer in direct contact with the second surface on the cold side of the coated component; and a first bond layer overlying the first aluminide layer on the cold side of the coated component.

There is further provided a combustor of a gas turbine engine comprising: a combustor liner having annular walls interconnected at upstream ends thereof to form a dome end of the combustor, the annular walls radially spaced apart to define a combustion chamber therebetween, each of the annular walls having an inner surface on a hot side of the combustor liner and an outer surface on a cold side of the combustor liner; a first aluminide layer in direct contact with at least a portion of the outer surface of the combustor walls on the cold side of the combustor liner; and a first bond layer overlying at least a portion of the first aluminide layer on the outer surface of the combustor walls on the cold side of the combustor liner.

### BRIEF DESCRIPTION OF THE DRAWINGS

Reference is now made to the accompanying figures in which:

FIG. 1 is a schematic cross-sectional view of a gas turbine engine;

FIG. 2 is a schematic cross-sectional view of a gas turbine combustor having a coated heat shield according to an embodiment;

FIG. 3 is a cross-sectional view of a coated component according to an embodiment;

FIG. 4 is a flow chart of a method of forming a thermal coating system according to an embodiment; and

FIG. 5 is a flow chart of a method of forming a thermal coating system according to another embodiment, with an additional roughening/packing step.

### DETAILED DESCRIPTION

According to an aspect, there is provided a coated component 10 of a gas turbine engine 11.

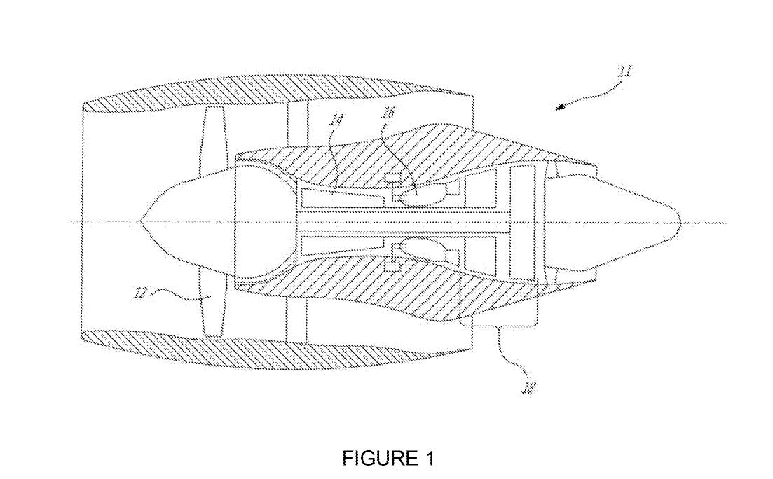

FIG. 1 illustrates a gas turbine engine 11 comprising in serial flow communication a fan 12 through which ambient air is propelled, a compressor section 14 for pressurizing the air, a combustor 16 in which the compressed air is mixed with fuel and ignited for generating an annular stream of hot combustion gases, and a turbine section 18 extracting energy from the combustion gases. The coated component 10 can therefore be a compressor, a combustor, or a turbine section. In an embodiment, the coated component is a combustor 16.

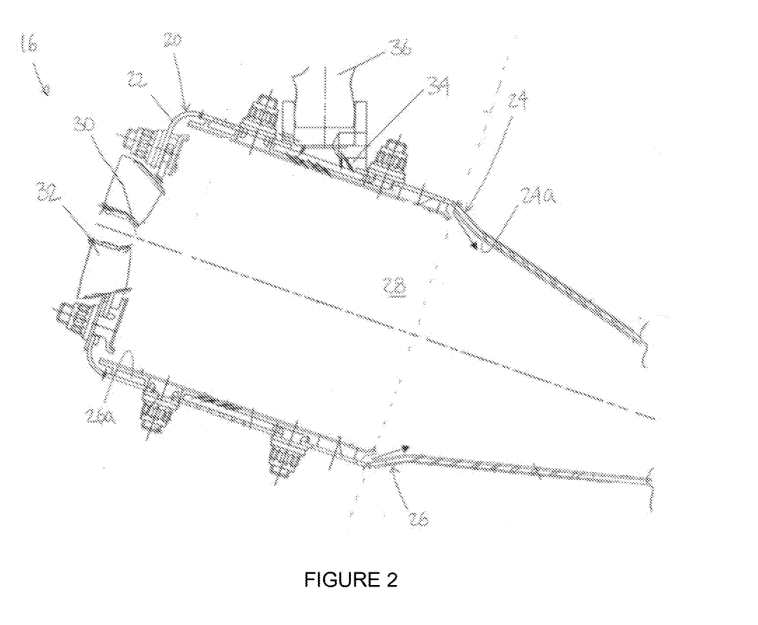

Referring to FIG. 2, a section of the combustor 16 is generally illustrated. The combustor 16 includes a combustor liner 20 with two concentric annular walls 24, 26 having interconnected upstream ends defining a dome end 22. A combustion chamber 28 is defined between the inner surfaces 24a, 26a of the annular walls 24, 26. The dome end 22 includes a circumferential array of spaced apart fuel nozzle holes 30 defined therethrough (only one of which is shown), each of which receiving the tip of a respective fuel nozzle 32. Support boss areas 34 are defined in the outer wall 24, which receive support members 36 (only one of which is shown) supporting the combustor 16 within the engine 10.

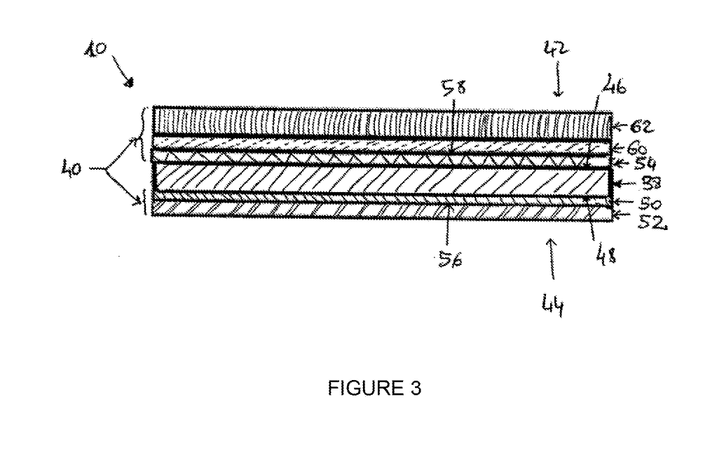

In a particular embodiment, illustrated in FIG. 3, the coated component 10 comprises a metallic substrate 38 and a thermal coating system 40. The coated component 10 has a hot side 42 adapted to be exposed to hot combustion gases. For example, in a gas turbine engine, a combustor generates a high-temperature gas that enters a turbine under high-pressure and expands down to an exhaust. The hot side 42 of the coated component 10 need to be thermally insulated. The coated component 10 also comprises a cold side 44 that is not exposed to hot combustion gases. The cold side 44 can be opposite to the hot side 42.

In a particular embodiment, the metallic substrate 38 forms a base structure of the coated component 10. The metallic substrate 38 can be one of a nickel-base alloy substrate, a cobalt-base alloy substrate, and a titanium-base alloy substrate. As used herein, “nickel-base”, “cobalt-base” , and “titanium-base” mean that the composition of the substrate has respectively more nickel, cobalt and titanium present than any other element. The metallic substrate 38 can define a panel, such as a combustor heat shield, a combustor liner, an exhaust wall, or a turbine blade. In a particular embodiment, the metallic substrate 38 is the combustor liner 20 as shown in FIG. 2.

Referring to FIG. 3, the metallic substrate 38 has a first surface 46 (also referred to as the hot surface) on the hot side 42 of the coated component and a second surface 48 (also referred to as the cold surface) on the cold side 44 of the coated component. For example, in a combustor, the first surface 46 can be an inner surface of an annular wall of the combustor liner, while the second surface 48 can be an outer surface of the annular wall.

The thermal coating system 40, is applied to the first and the second surfaces 46, 48. In a particular embodiment, the thermal coating system 40 on the first surface 46 on the hot side 42 provides with thermal insulation while, on the second surface 48 on the cold side 44, the thermal coating system provides resistance to oxidation.

As shown in FIG. 3, the thermal coating system 40 comprises a first aluminide layer 50 applied on the second surface 48 on the cold side 44. The first aluminide layer 50 is in direct contact with the second surface 48. The aluminide layer provides oxidation resistance to the substrate. In a particular embodiment, the first aluminide layer 50 has an aluminum content of less than 50 wt % based on total weight of the aluminide layer. In a more particular embodiment, the first aluminide layer 50 has an aluminum content of between 20 and 40 wt %. More particularly still, the first aluminide layer 50 may have an aluminum content of between 25 and 35 wt %. The first aluminide layer 50 can further include silicon. The first aluminide layer 50 can also include other additives, such as but not limited to Yttrium, Hafnium, Chromium, or precious metals. In a particular embodiment, the first aluminide layer has a thickness of from 0.0002 to 0.004 inch. In one particular embodiment, the first aluminide layer has a thickness of about 0.004 inch.

FIG. 3 also shows that a first bond layer 52 is applied on the cold side 44 of the substrate 38, overlying the first aluminide layer 50. As used herein the term “bond layer” refers to material containing various metal alloys such as MCrAlY alloys, where M is a metal such as iron, nickel, platinum, cobalt or alloys thereof. The term “MCrAlX” refers to a variety of bond coatings that may be employed as environmental coatings or bond coats in thermal coating systems. In a particular embodiment, the thickness of the first bond layer 52 is from 0.0001 to about 0.005 inch, most preferably about 0.003 inch. The first bond layer 52 may provide an improvement in the oxidation resistance of the first aluminide layer of up to 70% based on burner rig tests conducted.

A burner rig test can be conducted with 16 uncooled pins with various coatings, or just bare metal pins, mounted onto a carousel rotating at about 200 rpm. The carousel is put in front of a flame at control gas temperature of 2000° F. so that all the pins are under the same heat load. The assembly comprising the pins and the carousel can be alternately heated by the flame (57 minutes) and cooled by a cooler stream of air at 100° F. (3 minutes). The samples can be subjected to hundreds of thermal cycles, and every 40-80 cycles the surface condition of the pins can be studies with SEM and dimensions to determine the relative oxidation depth.

Still referring to FIG. 3, in a particular embodiment, the thermal coating system 40 also includes a second aluminide layer 54 on the first surface 46, on the hot side 42 of the coated component 10. The second aluminide layer 54 is in direct contact with the first surface 46. Therefore, the coated component 10 can comprise an aluminide layer on both the hot and cold sides 42, 44.

The chemical composition of the first and second aluminide layers 50, 54 can be similar. For example, the first and second aluminide layers 50, 54 can be applied in a single deposition process and therefore have the same chemical composition.

In a particular embodiment, the second aluminide layer 54 has an aluminum content of less than 50 wt % based on total weight of the aluminide layer. In a more particular embodiment, the second aluminide layer 54 has an aluminum content of between 20 and 40 wt %. More particularly still, the second aluminide layer 54 may have an aluminum content of between 25 and 35 wt %. The second aluminide layer 54 can further include silicon. The second aluminide layer 54 can also include other additives, such as, but not limited to, Yttrium, Hafnium, Chromium, or precious metals. In a particular embodiment, the second aluminide layer 54 has a thickness of from 0.0002 to 0.004 inch. In one particular embodiment, the second aluminide layer 54 has a thickness of about 0.004 inch.

In a particular embodiment, at least one of an outer surface 56, 58 of the first and the second aluminide layers 50, 54 can be roughened and/or packed before applying any additional layer thereon. The roughened outer surface 56, 58 preferably have a roughness of from about 80 Ra to about 150 Ra. The roughness can be similar to the roughness of the first and the second surface 46, 48 upon which the first and the second aluminide layers 50, 54 are applied. Roughening the outer surfaces 56, 58 improves the adherence of overlying coating layers. In a particular embodiment, both outer surfaces 56, 58 are roughened. Also, both outer surfaces 56, 58 can be packed.

Also shown in FIG. 3, overlying the second aluminide layer 54, and as described in conventional thermal coating systems, the present thermal coating system 40 comprises successively a second bond layer 60 and a ceramic layer 62 on the hot side 42.

In a particular embodiment, the second bond layer 60 has a composition similar to the composition of the first bond layer 52, as described herein. For example, the first and the second bond layers 52, 60 can be applied in a single deposition step and therefore have the same composition.

In a particular embodiment, the ceramic layer 62 comprises coating materials that are capable of reducing heat flow to the metallic substrate 38. The ceramic layer 62 must form a thermal barrier and, as a consequence, has a melting point of at least 2000° F. (1093° C.). Coating materials used in the ceramic layer 62 can comprise aluminum oxide (Al₂O₃), in unhydrated and/or hydrated forms. The ceramic layer 62 can also include zirconias, and more particularly chemically stabilized zirconias (yttria-stabilized zirconias, ceria-stabilized zirconias, calcia-stabilized zirconias, scandia-stabilized zirconias, magnesia-stabilized zirconias, india-stabilized zirconias, ytterbia-stabilized zirconias or mixture thereof). In addition, the ceramic layer 62 is preferably from 0.01″ to 0.015 inch thick.

In contrast with the common understanding, which assumes that any contamination of the thermal coating system on the hot side of the coated component is to be avoided, it has been shown that the presence of the second aluminide layer 54 underlying the second bond layer 60 and the ceramic layer 62 provides improvement of the spallation life of the thermal coating system 40 on the hot side 42 of the coated component 10. Extensive burner rig tests that simulate the combustor hot environment can be done to assess the improvement in spallation life. More particularly, the spallation life of the thermal coating system 40 can be improved up to four time compared with conventional thermal coating systems, without aluminide layer.

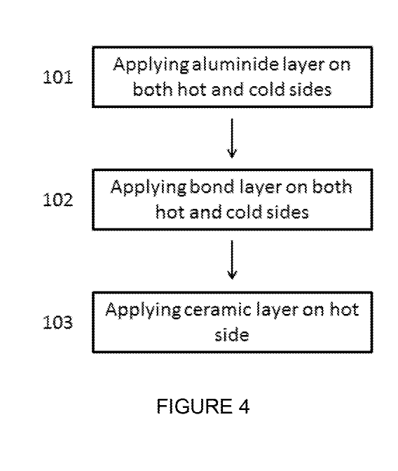

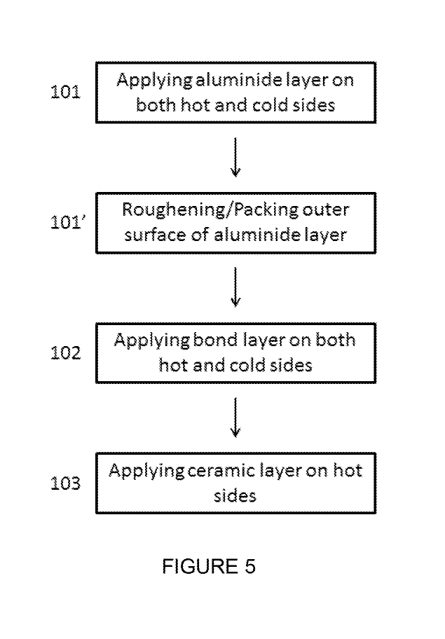

Turning now to FIGS. 4 and 5, a method of forming a thermal coating system on a component will now be described. The component of the present method is as described herein for the coated component 10. The thermal coating system is formed over a metallic substrate of the component, the metallic substrate being as described herein.

As show in FIG. 4, the method comprises the step 101 of applying an aluminide layer on both the hot surface and the cold surface of the component. In a particular embodiment, the aluminide layer is applied on the cold surface and on the hot surface simultaneously in a single step 101. For example, the aluminide layer can be applied using chemical vapor deposition process, without the need of masking the hot side of the component. It is understood that the aluminide layer of the present method is as described herein for the first and second aluminide layer 50, 54 of the coated component 10.

As shown in FIG. 4, the method further comprises the step 102 of applying a bond layer on both the hot side and the cold side of the component. The bond layer can be applied on an outer surface of the aluminide layer, using any suitable process. Preferably, the bond layer is applied by air plasma spray process at atmospheric conditions. Such air plasma spray process does not necessitate any vacuum, thereby reducing the cost and complexity of the method. Air plasma spray also allows the bond layer to be applied in one or more specific locations on the component.

The bond layer is applied over the aluminide layer on the cold side of the component so that the resistance to oxidation provided by the aluminide layer is improved of up to 70%.

Finally, still referring to FIG. 4, the method comprises applying a ceramic layer of the hot side of the component 103, over an outer surface of the bond layer. The ceramic layer can also be applied using air plasma spray process, preferably under atmospheric conditions. The ceramic layer provides thermal insulation to the metallic substrate of the coated component, and as such can be applied at specific locations over the substrate, i.e. where thermal protection is needed.

Now referring to FIG. 5, in another embodiment, the method also comprises the step 101′ of roughening and/or packing an outer surface of the aluminide layer before step 102 and 103. For example, the outer surface of the aluminide layer on at least one of the cold side and the hot side of the component can be roughened before applying the bond layer. In a particular embodiment, the aluminide layer is roughened and/or packed on both the hot side and the cold side of the component. The roughening step can be performed by light grit blasting of the aluminide layer. The roughened outer surface of the aluminide layer can have a roughness of from about 80 Ra to about 150 Ra. The surface can be similar to the roughness of the hot and the cold surfaces of the substrate. The outer surface of the aluminide layer can also be packed with peening for better adhesion.

The above description is meant to be exemplary only, and one skilled in the art will recognize that changes may be made to the embodiments described without departing from the scope of the invention disclosed. For example, any suitable material having the properties described with respect to the aluminide layer, bond layer or ceramic layer may be used. Any suitable method of applying the different layers may be used. Still other modifications which fall within the scope of the present invention will be apparent to those skilled in the art, in light of a review of this disclosure, and such modifications are intended to fall within the appended claims.

1. A method of applying a thermal coating to a gas turbine engine component, the method comprising the steps of:
applying a first aluminide layer to a hot surface of the component, the hot surface in use adapted to be exposed to a hot environment of the gas turbine engine;
applying a second aluminide layer to a cold surface of the component, the cold surface opposed to the hot surface;
applying a first bond layer over the first aluminide layer on the hot surface of the component;
applying a second bond layer over the aluminide layer on the cold surface of the component; and
applying a ceramic layer on the first bond layer on the hot surface of the component.

2. The method as defined in claim 1, wherein the first and the second aluminide layers are applied on the cold surface and the hot surface simultaneously in a single step.

3. The method as defined in claim 1, wherein the first and the second aluminide layer are applied using a chemical vapor deposition process.

4. The method as defined in claim 1, further including at least one of roughening and packing at least a portion of an outer surface of the first and the second aluminide layers before applying the first and the second bond layers.

5. The method as defined in claim 1, wherein at least one of the first bond layer, the second bond layer and the ceramic layer are applied using air plasma spraying under atmospheric pressure conditions.

6. A coated component of a gas turbine engine having a hot side adapted to be exposed to hot combustion gases and a cold side opposite the hot side, the coated component comprising:
a metallic substrate forming a base structure of the coated component, the metallic substrate having a first surface on the hot side of the coated component and a second surface on the cold side of the coated component; and
a thermal coating system on the metallic substrate, the thermal coating system including:
a first aluminide layer in direct contact with the second surface on the cold side of the coated component; and
a first bond layer overlying the first aluminide layer on the cold side of the coated component.

7. The coated component as defined in claim 6, further including:
a second aluminide layer in direct contact with the first surface on the hot side of the coated component;
a second bond layer overlying the second aluminide layer on the hot side of the coated component; and
a ceramic layer overlying the second bond layer on the hot side of the coated component, the ceramic layer forming an outermost layer on the hot side of the coated component to provide thermal protection against the hot combustion gases.

8. The coated component as defined in claim 7, wherein the first and the second aluminide layers have substantially the same composition.

9. The coated component as defined in claim 7, wherein the first and the second aluminide layers have a thickness of from 0.002 to 0.004 inches.

10. The coated component of claim 7, wherein an outer surface of the second aluminide layer is roughen and/or packed.

11. The coated component of claim 6, wherein the metallic substrate is one of nickel base alloy substrate, cobalt base alloy substrate, and titanium base alloy substrate.

12. A combustor of a gas turbine engine comprising:
a combustor liner having annular walls interconnected at upstream ends thereof to form a dome end of the combustor, the annular walls radially spaced apart to define a combustion chamber therebetween, each of the annular walls having an inner surface on a hot side of the combustor liner and an outer surface on a cold side of the combustor liner;
a first aluminide layer in direct contact with at least a portion of the outer surface of the combustor walls on the cold side of the combustor liner; and
a first bond layer overlying at least a portion of the first aluminide layer on the outer surface of the combustor walls on the cold side of the combustor liner.

13. The combustor as defined in claim 12, further including
a second aluminide layer in direct contact with at least a portion of the inner surface of the combustor walls on the hot side of the combustor liner;
a second bond layer overlying at least a portion of the second aluminide layer on the inner surface of the combustor walls on the hot side of the combustor liner; and
a ceramic layer overlying at least a portion of the second bond layer, the ceramic layer forming an outermost layer on the inner surface of the combustor walls on the hot side of the combustor liner to provide thermal protection against the hot combustion gases.

14. The combustor as defined in claim 13, wherein the first and the second aluminide layers have substantially the same composition.

15. The combustor as defined in claim 13, wherein the first and the second aluminide layers have a thickness of from 0.002 to 0.004 inches.

16. The combustor as defined in claim 13, wherein an outer surface of at least one of the first and the second aluminide layer is at least one of roughened and packed.

17. The combustor of claim 12, wherein the combustor liner is one of nickel base alloy liner, cobalt base alloy liner, and titanium base alloy liner.
